(19) United States
(12) Patent Application Publication
(10) Pub. No.: US 2017/0054430 A1
(43) Pub. Date: Feb. 23, 2017

(54) BAW RESONATOR HAVING MULTI-LAYER ELECTRODE AND BO RING CLOSE TO PIEZOELECTRIC LAYER

(71) Applicant: RF Micro Devices, Inc., Greensboro, NC (US)

(72) Inventors: Gernot Fattinger, Sorrento, FL (US); Alireza Tajic, Winter Springs, FL (US); Fabien Dumont, Wekiva Springs, FL (US); Paul Stokes, Orlando, FL (US); Frida Stromqvist Vetelino, Orlando, FL (US)

(21) Appl. No.: 14/877,324

(22) Filed: Oct. 7, 2015

Related U.S. Application Data
(60) Provisional application No. 62/207,971, filed on Aug. 21, 2015.

(51) Int. Cl. H03H 9/54; H03H 9/17; H03H 3/007

(52) U.S. Cl. CPC H03H 9/171; H03H 3/0072

(57) ABSTRACT

Embodiments of a Bulk Acoustic Wave (BAW) resonator having a high quality factor (Q) and methods of fabrication thereof are disclosed. In some embodiments, a BAW resonator includes a piezoelectric layer, a first electrode on a first surface of the piezoelectric layer, and a second multi-layer electrode on a second surface of the piezoelectric layer opposite the first electrode on the first surface of the piezoelectric layer. In addition, the BAW resonator includes a Border (BO) ring positioned within the second multi-layer electrode around a periphery of an active region of the BAW resonator. The BO ring is either at a position within the second multi-layer electrode between two adjacent layers of the second multi-layer electrode or at a position within the second multi-layer electrode that is adjacent to the piezoelectric layer. In this manner, the quality factor (Q) of the BAW resonator is improved.

### RELATED APPLICATIONS

This application claims the benefit of provisional patent application Se. No. 62/207,971, filed Aug. 21, 2015, the disclosure of which is hereby incorporated herein by reference in its entirety.

### FIELD OF THE DISCLOSURE

The present disclosure relates to a Bulk Acoustic Wave (BAW) resonator.

Background

Due to, among other things, their small size, high Q values, and very low insertion losses at microwave frequencies, particularly those above 1.5 Gigahertz (GHz), Bulk Acoustic Wave (BAW) filters have become the filter of choice for many modern wireless applications. In particular, BAW filters are the filter of choice for many 3^{rd} Generation (3G) and 4^{th} Generation (4G) wireless devices. For instance, virtually all Long Term Evolution (LTE) compatible mobile devices operating in LTE frequency bands above 1.9 GHz utilize BAW filters.

For mobile devices, the low insertion loss of the BAW filter provides many advantages such as, e.g., improved battery life, compensation for higher losses associated with the need to support many frequency bands in a single mobile device, etc.

One example of a conventional BAW resonator 10 is illustrated in FIG. 1. In this example, the BAW resonator 10 is, in particular, a Solidly Mounted Resonator (SMR) type BAW resonator 10. As illustrated, the BAW resonator 10 includes a piezoelectric layer 12 (which is sometimes referred to as a piezoelectric plate) between a bottom electrode 14 and a top electrode 16. Since the BAW resonator 10 is a SMR type BAW resonator 10, the BAW resonator 10 also includes a reflector 18 (which is more specifically referred to as a Bragg reflector) that includes multiple layers 20-28 of alternating materials with varying refractive index. In this example, the BAW resonator 10 also includes a Border (BO) ring 30 on the top surface of the top electrode 16 around the periphery of the top electrode 16 within what is referred to herein as a BO region 32 of the BAW resonator 10. The BO region 32 is the peripheral region of an active region 34 of the BAW resonator 10.

In operation, acoustic waves in the piezoelectric layer 12 within the active region 34 of the BAW resonator 10 are excited by an electrical signal applied to the bottom and top electrodes 14 and 16. The active region 34 is the region of the BAW resonator 10 that is electrically driven. In other words, the active region 34 is the region of the BAW resonator 10 consisting of, in this example, the bottom electrode 14, the top electrode 16, the portion of the piezoelectric layer 12 between the bottom and top electrodes 14 and 16, and the portion of the reflector 18 below the bottom electrode 14. Conversely, an outer region 36 of the BAW resonator 10 is a region of the BAW resonator 10 that is not electrically driven (i.e., the area outside of the active region 34). The frequency at which resonance of the acoustic waves occurs is a function of the thickness of the piezoelectric layer 12 and the mass of the bottom and top electrodes 14 and 16. At high frequencies (e.g., greater than 1.5 GHz), the thickness of the piezoelectric layer 12 is only micrometers thick and, as such, the BAW resonator 10 is fabricated using thin-film techniques.

Ideally, in order to achieve a high Q value, the mechanical energy should be contained, or trapped, within the active region 34 of the BAW resonator 10. The reflector 18 operates to prevent acoustic waves from leaking longitudinally, or vertically, from the BAW resonator 10 into the substrate (not shown, but below the reflector 18). Notably, in a Film Bulk Acoustic Resonator (FBAR) type BAW resonator, an air cavity is used instead of the reflector 18, where the air cavity likewise prevents acoustic waves from escaping into the substrate.

One issue that arises with the BAW resonator 10 in implementation is that, due to, e.g., the finite lateral dimension of the structure of the BAW resonator 10, lateral acoustic waves can also propagate. Thus, part of the mechanical energy contained in the fundamental thickness, or longitudinal, mode leaks into lateral modes, which results in degradation of the quality factor (Q) of the BAW resonator 10. As shown in FIG. 2 (solid curve), if there is no BO region 32 (i.e., no BO ring 30), lateral standing waves become evident in the electrical behavior of the BAW resonator 10 in the form of spurious resonances leading to strong ripples in the passband of the BAW resonator 10.

In this regard, the performance of the BAW resonator 10 is improved by the BO ring 30, which provides mass loading or thickened edge loading around the periphery of the active region 34. The function of the BO ring 30 can be explained as follows. The BO ring 30 enables acoustic mismatch between the active region 34 and the outer region 36 to be avoided, providing a smooth transition of propagating waves in the active region 34 to evanescent waves in the outer region 36. To do so, the lateral propagation constant kₓ must be real within the active region 34 and purely imaginary within the outer region 36, as illustrated at the bottom of FIG. 1. In other words, the laterally propagating standing waves are in a spectrum of discrete wave modes inside the active region 34 and the BO region 32. Parameters (e.g., thickness and width) of the BO ring 30 are tuned in an attempt to match one of the excited wave modes inside the BO region 32 with the fundamental thickness mode in the active region 34. If perfect matching is achieved, due to the orthogonality of all of the discrete wave modes, none of the wave modes other than the fundamental thickness mode will be matched between the active region 34 and the BO region 32. In this manner, only the fundamental thickness wave mode can be excited. The quality factor (Q) of the BAW resonator 10 is maximized at the optimum parameters (e.g., thickness and width) of the BO ring 30. At the maximum quality factor (Q), the highest level of spurious mode suppression is achieved, as illustrated in FIG. 2 (dashed curve).

In practice, perfect matching between the active region 34 and the BO region 32, and thus the maximum quality factor (Q), is difficult, if not practically impossible, to achieve. As such, there remains a need for a BAW resonator having an improved quality factor (Q), and methods of manufacturing thereof.

### SUMMARY

Embodiments of a Bulk Acoustic Wave (BAW) resonator having a high quality factor (Q) and methods of fabrication thereof are disclosed. In some embodiments, a BAW resonator includes a piezoelectric layer, a first electrode on a first surface of the piezoelectric layer, and a second multi-layer electrode on a second surface of the piezoelectric layer opposite the first electrode on the first surface of the piezoelectric layer. In addition, the BAW resonator includes a Border (BO) ring positioned within the second multi-layer electrode around a periphery of an active region of the BAW resonator. Rather than being positioned on a surface of the second multi-layer electrode opposite of, or away from, the piezoelectric layer, the BO ring is either at a position within the second multi-layer electrode between two adjacent layers of the second multi-layer electrode or at a position within the second multi-layer electrode that is adjacent to the piezoelectric layer. In this manner, the BO ring is adjacent to or very near to the piezoelectric layer and, as a result, the quality factor (Q) of the BAW resonator is improved.

In some embodiments, the BO ring is positioned within the second multi-layer electrode at the position between two adjacent layers of the second multi-layer electrode. Further, in some embodiments, the second multi-layer electrode includes a first electrode layer on the surface of the piezoelectric layer opposite the first electrode and a second electrode layer on a surface of the first electrode layer opposite the piezoelectric layer, where the two adjacent layers between which the BO ring is positioned are the first electrode layer and the second electrode layer. Further, in some embodiments, the first electrode layer is formed of Tungsten, the second electrode layer is formed of Aluminum Copper, and the BO ring is formed of Tungsten.

In some embodiments, the BO ring is positioned within the second multi-layer electrode at the position within the second multi-layer electrode that is adjacent to the piezoelectric layer. Further, in some embodiments, the BO ring is on the surface of the piezoelectric layer opposite the first electrode, and the second multi-layer electrode includes a first electrode layer on a surface of the BO ring opposite the piezoelectric layer and on the surface of the piezoelectric layer opposite the first electrode within the BO ring and a second electrode layer on a surface of the first electrode layer opposite the piezoelectric layer. Further, in some embodiments, the first electrode layer is formed of Tungsten, the second electrode layer is formed of Aluminum Copper, and the BO ring is formed of Tungsten.

In some embodiments, the second multi-layer electrode is a top electrode of the BAW resonator. In other embodiments, the second multi-layer electrode is a bottom electrode of the BAW resonator.

In some embodiments, the BAW resonator is a Solidly Mounted Resonator (SMR) type BAW resonator. In other embodiments, the BAW resonator is a Film Bulk Acoustic Resonator (FBAR) type BAW resonator.

In some embodiments, a method of manufacturing a BAW resonator includes providing an initial structure comprising a piezoelectric layer and a first electrode on a first surface of the piezoelectric layer, providing a second multi-layer electrode on a second surface of the piezoelectric layer opposite the first electrode on the first surface of the piezoelectric layer, and providing a BO ring positioned within the second multi-layer electrode around a periphery of an active region of the BAW resonator. The BO ring is either at a position between two adjacent layers of the second multi-layer electrode or a position within the second multi-layer electrode that is adjacent to the piezoelectric layer.

In some embodiments, providing the BO ring comprises providing the BO ring such that the BO ring is positioned within the second multi-layer electrode at the position between two adjacent layers of the second multi-layer electrode. Further, in some embodiments, providing the second multi-layer electrode includes providing a first electrode layer on the surface of the piezoelectric layer opposite the first electrode and providing a second electrode layer on a surface of the first electrode layer opposite the piezoelectric layer, and providing the BO ring such that the BO ring is positioned within the second multi-layer electrode at the position between two adjacent layers of the second multi-layer electrode comprises providing the BO ring such that the BO ring is positioned between the first electrode layer and the second electrode layer. Further, in some embodiments, the first electrode layer is formed of Tungsten, the second electrode layer is formed of Aluminum Copper, and the BO ring is formed of Tungsten.

In some embodiments, providing the BO ring comprises providing the BO ring such that the BO ring is positioned within the second multi-layer electrode at the position within the second multi-layer electrode that is adjacent to the piezoelectric layer. Further, in some embodiments, providing the BO ring includes providing the BO ring on the surface of the piezoelectric layer opposite the first electrode, and providing the second multi-layer electrode includes providing a first electrode layer on a surface of the BO ring opposite the piezoelectric layer and on the surface of the piezoelectric layer opposite the first electrode within the BO ring and providing a second electrode layer on a surface of the first electrode layer opposite the piezoelectric layer. Further, in some embodiments, the first electrode layer is formed of Tungsten, the second electrode layer is formed of Aluminum Copper, and the BO ring is formed of Tungsten.

In some embodiments, the second multi-layer electrode is a top electrode of the BAW resonator. In other embodiments, the second multi-layer electrode is a bottom electrode of the BAW resonator.

In some embodiments, the BAW resonator is a SMR type BAW resonator. In other embodiments, the BAW resonator is a FBAR type BAW resonator.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates one example of a conventional Bulk Acoustic Wave (BAW) resonator including a Border (BO) ring providing mass loading;

FIG. 2 graphically illustrates spurious modes in a passband of the BAW resonator with and without a BO ring;

FIGS. 3A and 3B illustrate a BAW resonator having an increased quality factor (Q) and reduced spurious modes within a passband of the BAW resonator, as compared to a reference BAW resonator, according to some embodiments of the present disclosure;

FIGS. 4 through 6 graphically illustrate relationships between various parameters of the BAW resonator of FIG. 3B and a width of the BO region (i.e., the width of the BO ring) according to some embodiments of the present disclosure; and

FIGS. 7A through 7E graphically illustrate a process for fabricating the BAW resonator of FIG. 3B according to some embodiments of the present disclosure.

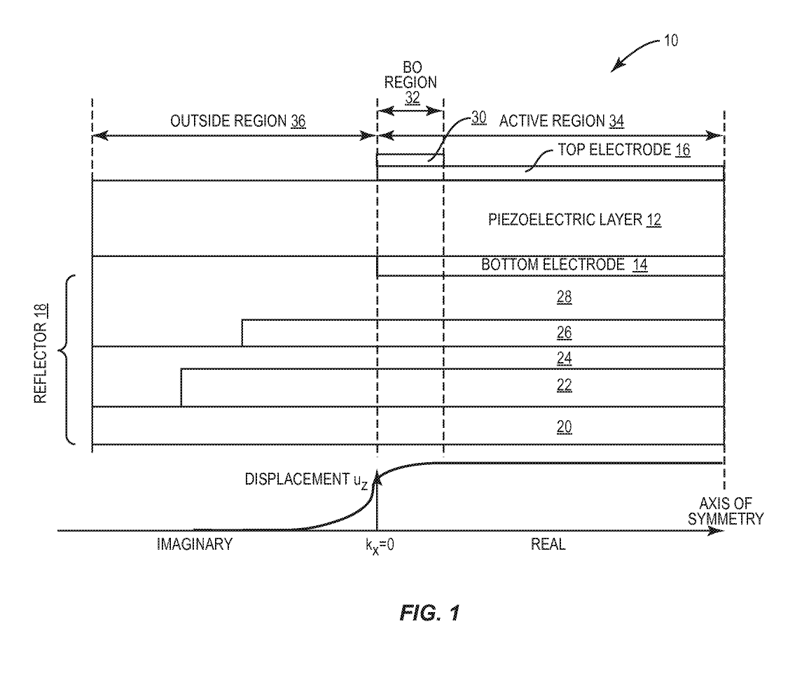

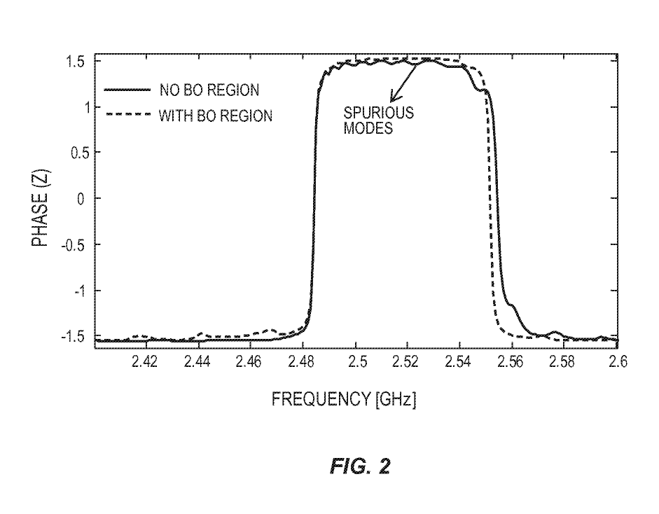

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

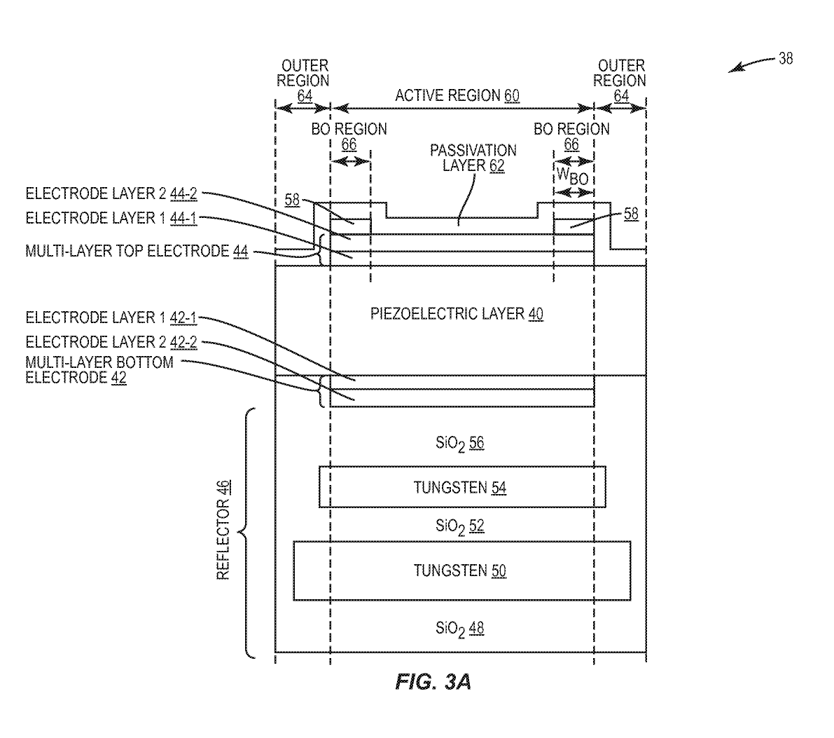

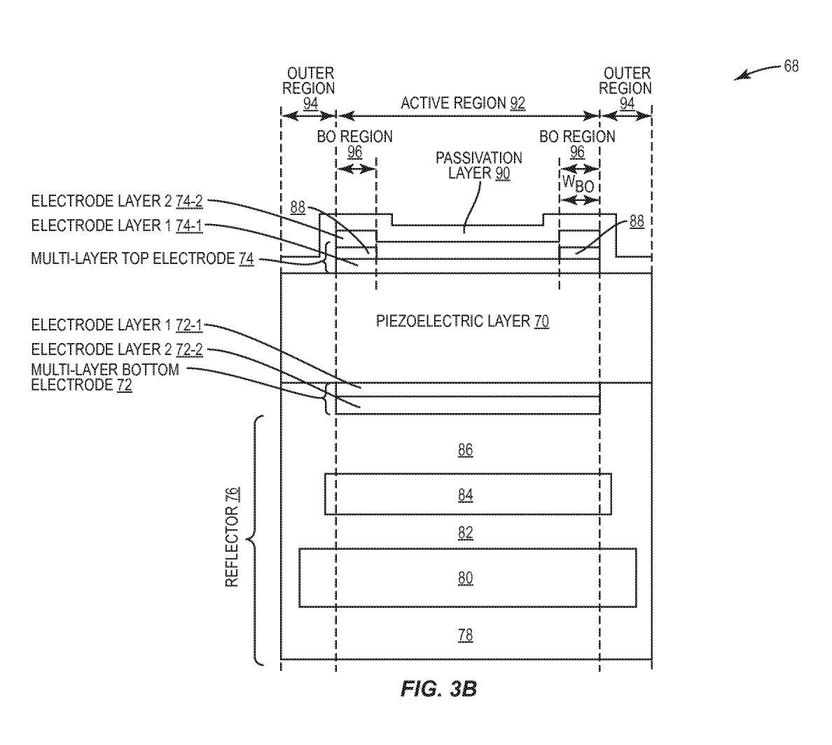

Embodiments of a Bulk Acoustic Wave (BAW) resonator are disclosed in which a Border (BO) ring providing mass loading at the periphery of an active region of the BAW resonator is located adjacent to or very near a piezoelectric layer of the BAW resonator. In this manner, a quality factor (Q) of the BAW resonator is improved and spurious modes within a passband of the BAW resonator are suppressed. In this regard, FIGS. 3A and 3B illustrate a BAW resonator having an improved quality factor (Q) and suppressed spurious modes within a passband of the BAW resonator, as compared to a reference BAW resonator, according to some embodiments of the present disclosure. More specifically, FIG. 3A illustrates a reference BAW resonator 38. In this example, the reference BAW resonator 38 includes a piezoelectric layer 40 (which is sometimes referred to as a piezoelectric plate). The piezoelectric layer 40 may be any suitable type of piezoelectric material such as, for example, Aluminum Nitride (AIN) or Zinc Oxide (Zn0). Further, the piezoelectric layer 40 may be a single layer of piezoelectric material or may include multiple sublayers of the same or different piezoelectric materials.

The reference BAW resonator 38 further includes a multi-layer bottom electrode 42 on a bottom surface of the piezoelectric layer 40 and a multi-layer top electrode 44 on a top surface of the piezoelectric layer 40 opposite the multi-layer bottom electrode 42. Each of the multi-layer bottom and top electrodes 42 and 44 includes two or more layers of the same or different materials. In this particular example, the multi-layer bottom electrode 42 includes a first electrode layer 42-1 and a second electrode layer 42-2. In one particular implementation, the first electrode layer 42-1 is Tungsten, and the second electrode layer 42-2 is Aluminum Copper; however, the first and second electrode layers 42-1 and 42-2 are not limited thereto. In the same manner, in this example, the multi-layer top electrode 44 includes a first electrode layer 44-1 and a second electrode layer 44-2. In one particular implementation, the first electrode layer 44-1 is Tungsten, and the second electrode layer 44-2 is Aluminum Copper; however, the first and second electrode layers 44-1 and 44-2 are not limited thereto.

In this example, the reference BAW resonator 38 is a Solidly Mounted Resonator (SMR) type BAW resonator and, as such, the reference BAW resonator 38 also includes a reflector 46 (which is more specifically referred to as a Bragg reflector) that includes multiple alternating layers 48-56 of alternating materials with varying refractive index. In this example, the layers 48-56 are alternating layers of Silicon Dioxide (SiO₂) and Tungsten.

The reference BAW resonator 38 also includes a BO ring 58 on the top surface of the multi-layer top electrode 44. The BO ring 58 is a “ring” or “frame” of material that is on the top surface of the multi-layer top electrode 44 around the periphery of the multi-layer top electrode 44 (and thus around a periphery of an active region 60 of the reference BAW resonator 38). Lastly, the reference BAW resonator 38 includes a passivation layer 62 on the surface of the reference

BAW resonator 38 over both the active region 60 and an outer region 64 of the reference BAW resonator 38. While the passivation layer 62 can be of any suitable material, in one example, the passivation layer 62 is Silicon Nitride (SiN). Notably, the region in which the BO ring 58 is located is referred to herein as a BO region 66.

Notably, as used herein, the active region 60 is the region of the reference BAW resonator 38 that is electrically driven, which in the example of FIG. 3A is the region consisting of the multi-layer bottom electrode 42, the multi-layer top electrode 44, the portion of the piezoelectric layer 40 between the multi-layer bottom and top electrodes 42 and 44, and the portion of the reflector 46 beneath the multi-layer bottom electrode 42. The outer region 64 is the region of the reference BAW resonator 38 that is not electrically driven or, in other words, the region of the reference BAW resonator 38 that is outside of the active region 60. Again, the BO region 66 is the region in which the BO ring 58 is

As will be appreciated by one of ordinary skill in the art, the BO ring 58 provides mass loading or thickened edge loading around the periphery of the active region 60. The BO ring 58 enables acoustic mismatch between the active region 60 and the outer region 64 to be avoided, providing a smooth transition of propagating waves in the active region 60 to evanescent waves in the outer region 64. In this manner, only the fundamental thickness wave mode can be excited in the active region 60 and, as a result, the quality factor (Q) of the reference BAW resonator 38 is improved and spurious modes in the passband of the reference BAW resonator 38 are suppressed.

Particularly with the multi-layer top electrode 44, the BO ring 58 of the reference BAW resonator 38 is not close to the piezoelectric layer 40. As a result, the reference BAW resonator 38 exhibits significant lateral leakage of mechanical energy that contributes to a degraded quality factor (Q). FIG. 3B illustrates a BAW resonator 66 that addresses this issue by utilizing a high impedance layer adjacent to or very close to the surface of the piezoelectric layer. This leads to a higher quality factor (Q) as compared to the reference BO resonator 38 due to better energy confinement and suppression of spurious modes, as well as higher electro-mechanical coupling and less BO mode due to a narrower optimum BO width.

In embodiment of FIG. 3B, the BAW resonator 68 includes a piezoelectric layer 70 (which is sometimes referred to as a piezoelectric plate), a multi-layer bottom electrode 72, a multi-layer top electrode 74, a reflector 76 including layers 78-86, a BO ring 88, and a passivation layer 90. The BAW resonator 68 includes an active region 92, an outer region 94, and a BO region 96. Other than the location of the BO ring 88, the BAW resonator 68 is exactly the same as the reference BAW resonator 38; as such the details of the various components and layers of the BAW resonator 68 are not repeated. Notably, a “reference BAW resonator” for a particular BAW resonator (e.g., the BAW resonator 68) is a BAW resonator that is exactly the same except for the closer

In general, in the BAW resonator 68, rather than being located, or positioned, on the top surface of the multi-layer top electrode 74, which is relatively far from the surface of the piezoelectric layer 70, the BO ring 88 is located within the multi-layer top electrode 74 adjacent to or relatively near the surface of the piezoelectric layer 70. In this particular example, the BO ring 88 is positioned between the first and second electrode layers 74-1 and 74-2 of the multi-layer top electrode 74. However, the position of the BO ring 88 is not limited thereto. The BO ring 88 may be positioned between the piezoelectric layer 70 and the first electrode layer 74-1 or, as in this example, between two adjacent layers of the multi-layer top electrode 74. In one particular embodiment, both the BO ring 88 and the first electrode layer 74-1 of the multi-layer top electrode 74 are the same material (e.g., Tungsten). As such, in this context, the BO ring 88 can be thought of conceptually as being either on top of or below the first electrode layer 74-1.

In general, the distance between the piezoelectric layer 70 and the BO ring 88 is less than the combined thickness of the first and second electrode layers 74-1 and 74-2 of the multi-layer top electrode 74. For example, in some particular embodiments, the distance between the piezoelectric layer 70 and the BO ring 88 is less than or equal to 50% of the combined thickness of the first and second electrode layers 74-1 and 74-2 of the multi-layer top electrode 74.

However, this ratio may vary depending on various implementation specific factors such as, for example, the materials used for the first and second electrode layers 74-1 and 74-2. In some other particular embodiments, the BO ring 88 is on (e.g., directly on) the surface of the piezoelectric layer 70 between the piezoelectric layer 70 and the first electrode layer 74-1 of the multi-layer top electrode 74. It should also be noted that, while the BO ring 88 is within the multi-layer top electrode 74 in this example, the BO ring 88 may alternatively be within the multi-layer bottom electrode 72.

The BO ring 88 is a high impedance layer. By placing this high impedance layer adjacent to or very close to the piezoelectric layer 70, the quality factor (Q) is increased due to better energy confinement and suppression of spurious modes, as well as higher electro-mechanical coupling and less BO mode due to a narrower optimum BO width (W_{BO}). In other words, layers close to the piezoelectric layer 70 usually have higher frequency sensitivity. Thus, for example, a Tungsten BO ring with a particular thickness would generate a higher frequency shift in the BO region, compared to that of the active region, when the BO ring is closer to the piezoelectric layer 70. In general, by being closer to the piezoelectric layer 70, the BO ring 88 can be thinner compared to a BO ring that is further away from the piezoelectric layer 70. This results in less topological difference between the BO region 96 and the active region 92 and, consequently, better mode matching between them. The higher quality factor (Q) of the BAW resonator 68 results in better insertion loss and steeper shoulders in a filter constructed from such BAW resonators. The higher electro-mechanical coupling of the BAW resonator 68 results in wider bandwidth and/or better return loss in a filter constructed from such BAW resonators. The lower BO mode of the BAW resonator 68 results in less passband loss in a filter constructed from such BAW resonators. All of these features will result in higher performance filters constructed from such BAW resonators.

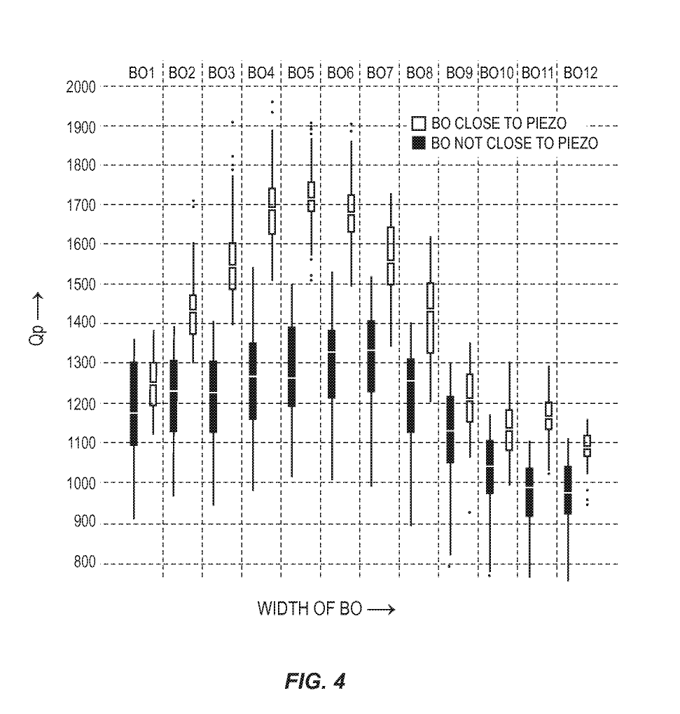

FIGS. 4 through 6 graphically illustrate relationships between various parameters of the BAW resonators 38 and 68 of FIGS. 3A and 3B, respectively, and a width (W_{BO}) of the BO regions 66 and 96 (i.e., the width of the BO rings 58 and 88), respectively, according to some embodiments of the present disclosure. These relationships may be used to, e.g., optimize the width (W_{BO}) of the BO region 96 to achieve a desired performance. In particular, FIG. 4 graphically illustrates a relationship between the width (W_{BO}) of the BO regions 66 and 96 and the quality factor (Q) for one example implementation of the BAW resonators 38 and 68, respectively. Here, BO1, BO2, BO3, etc. represent increasing values for the width (W_{BO}) of the BO regions 66 and 96 such that BO1<BO2<BO3, etc. From this illustration, it can be seen that, for the BAW resonator 68 where the BO ring 88 is close to the piezoelectric layer 70, the quality factor (Q) is maximized for BO5 and remains near the maximum value for BO4 and BO6. In contrast, for the reference BAW resonator 38 where the BO ring 58 is not close to the piezoelectric layer 40, the maximum value of the quality factor (Q) is much lower.

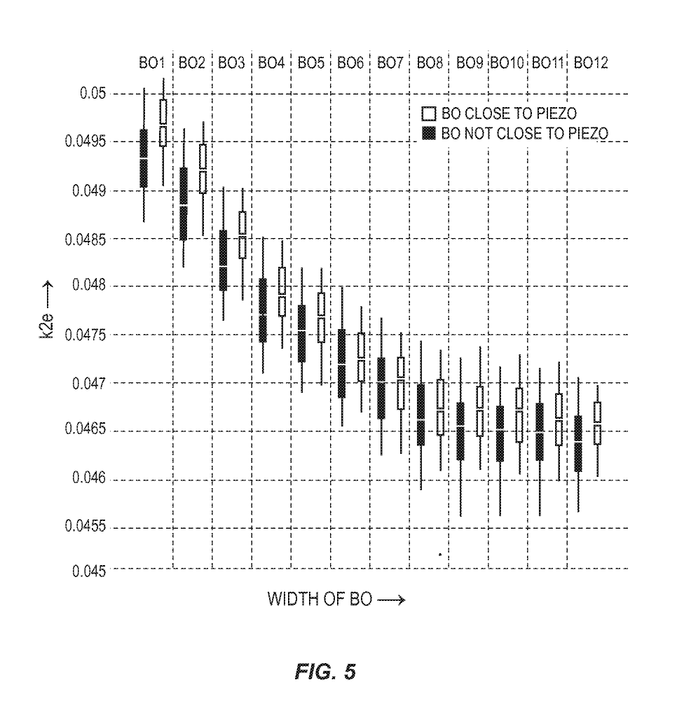

FIG. 5 graphically illustrates a relationship between the width (W₁₃₀) of the BO regions 66 and 96 and the electro-mechanical coupling (k2e) for one example implementation of the BAW resonators 38 and 68, respectively. Again,

BO1, BO2, BO3, etc. represent increasing values for the width (W_{BO}) of the BO regions 66 and 96 such that BO1<BO2<BO3, etc. From this illustration, it can be seen that, for any width (W_{BO}), the BAW resonator 68 where the BO ring 88 is close to the piezoelectric layer 70 has higher electro-mechanical coupling (k2e) than that in the reference BAW resonator 38 where the BO ring 58 is not close to the piezoelectric layer 40.

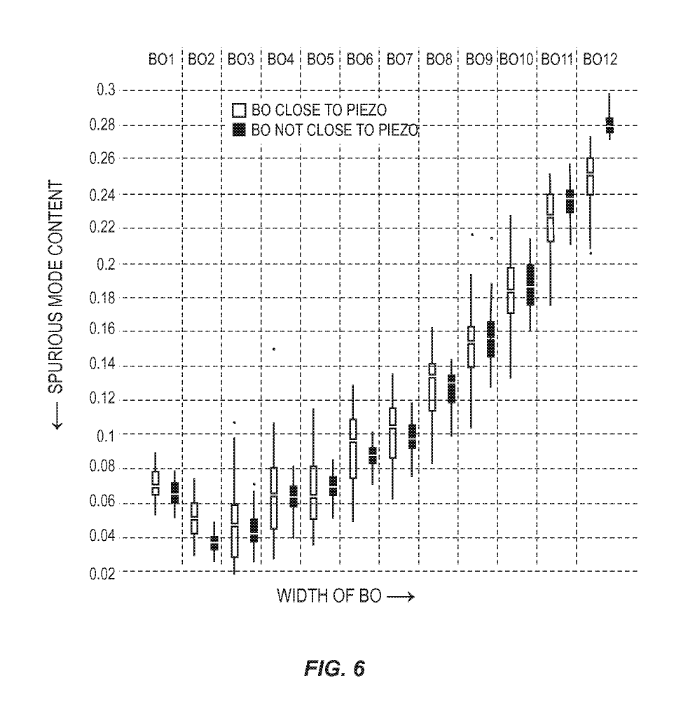

FIG. 6 graphically illustrates a relationship between the width (W₁₃₀) of the BO regions 66 and 96 and the spurious mode content for one example implementation of the BAW resonators 38 and 68, respectively. Again, BO1, BO2, BO3, etc. represent increasing values for the width (W_{BO}) of the BO regions 66 and 96 such that BO1<BO2<BO3, etc. FIG. 6 shows that the BAW resonator 68 has lower spurious mode contents than the reference BAW resonator 38 for some BO widths and higher spurious mode contents than the reference BAW resonator 38 for other BO widths. The fact is that when the BO ring 88 is moved closer to the piezoelectric layer 70, the optimum BO (the BO width with maximum Op and highest energy confinement) is moving towards the narrower BOs. This can be seen in FIG. 4 where the optimum BO is BO5, which is narrower than BO7 in which the reference resonator has maximum Op. So, by moving the BO ring 88 closer to the piezoelectric layer 70, the value of Op increases and the optimum BO width reduces. Thus, if other properties such as k2e or spurious mode contents in the passband are to be compared, those properties should be compared for the optimum BO width of the BAW resonator 68 (e.g., BO5) and the optimum BO width of the reference BAW resonator 38 (e.g., BO7). Better coupling and spurious suppression is achieved because of the narrower width of the BO ring 88 as compared to that of the reference BAW resonator 38.

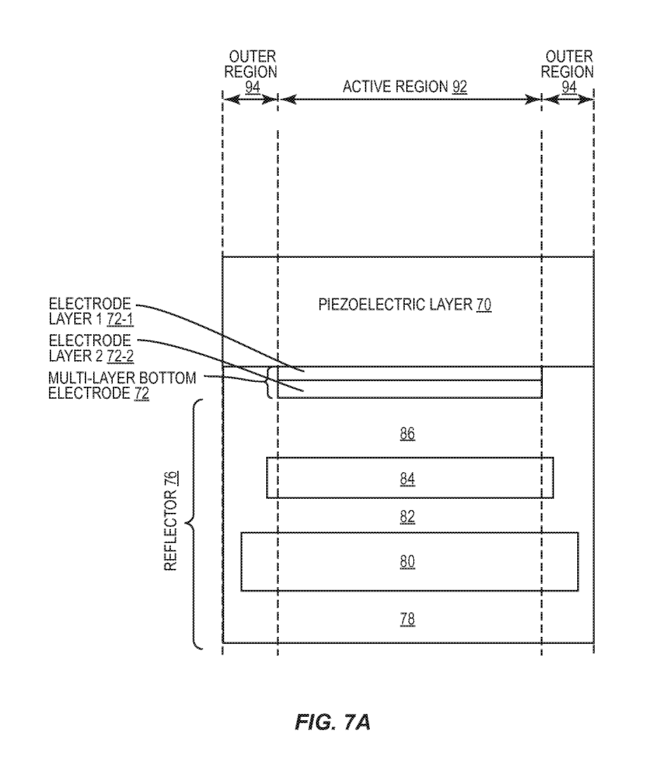

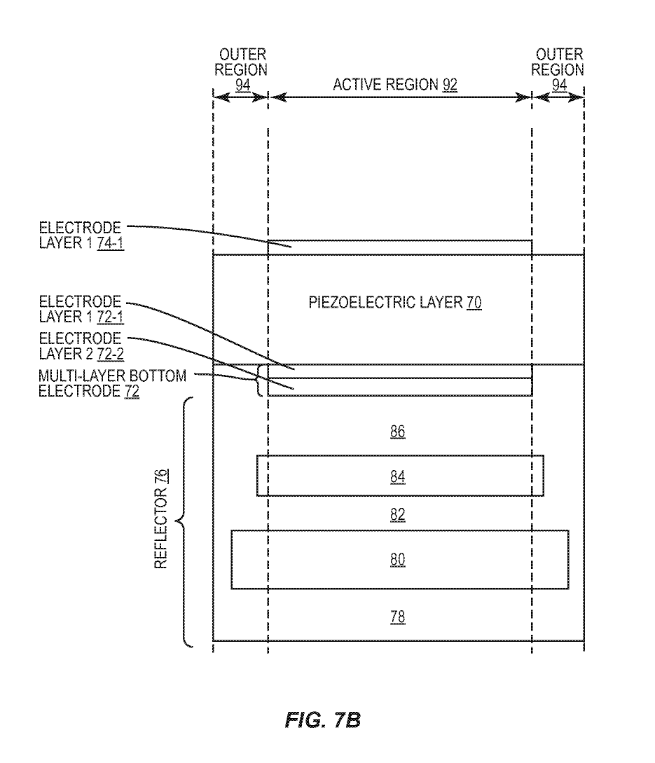

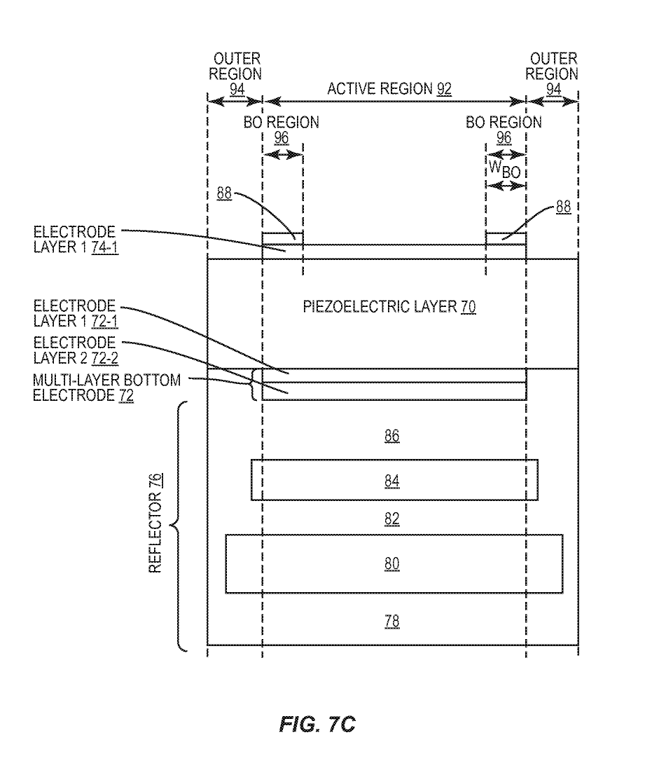

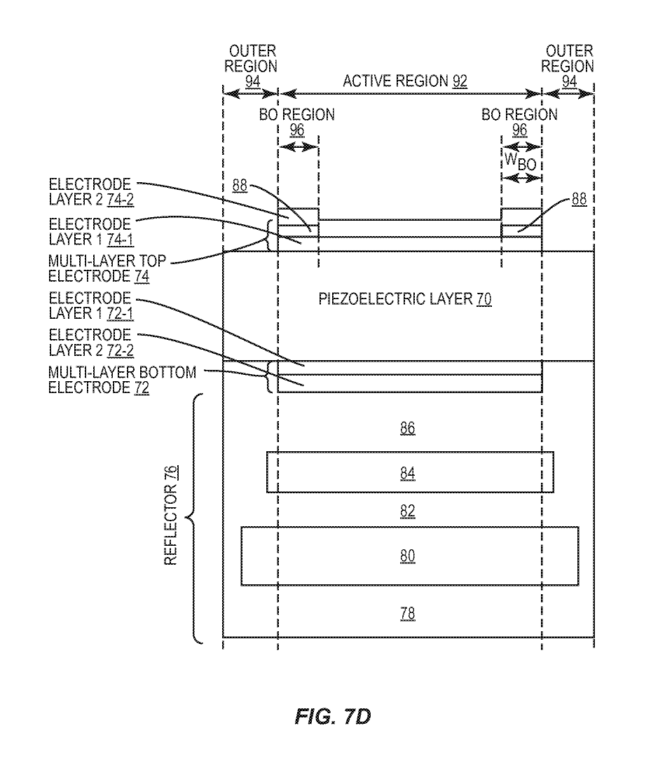

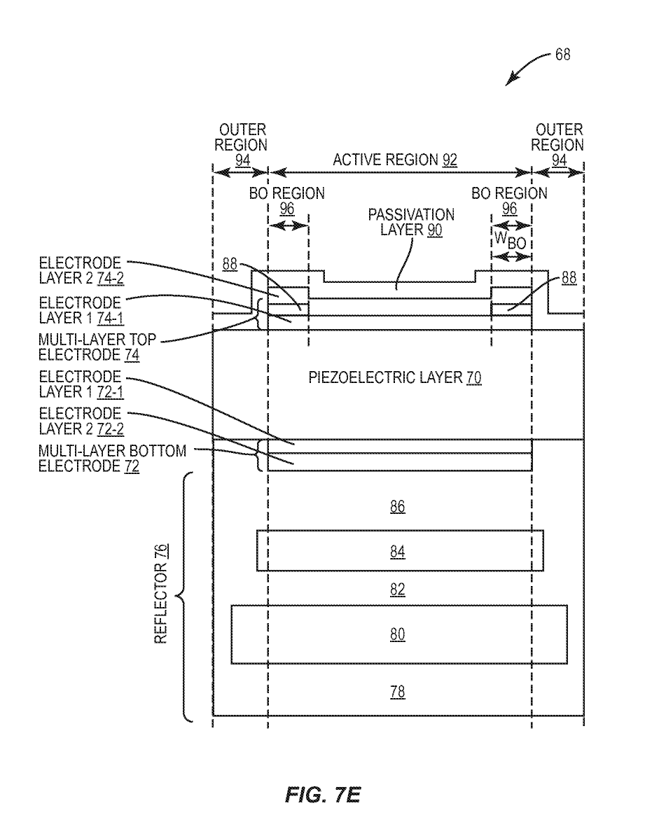

FIGS. 7A through 7E graphically illustrate a process for fabricating the BAW resonator 68 of FIG. 3B according to some embodiments of the present disclosure. As illustrated, the process begins with an initial structure that includes the piezoelectric layer 70, the multi-layer bottom electrode 72, and, in this example, the reflector 76. Note, however, that the initial structure may vary depending on the particular implementation. The initial structure may be fabricated using any appropriate process.

Next, in this example, the first electrode layer 74-1 of the multi-layer top electrode 74 is provided on (e.g., formed or deposited on) the surface of the piezoelectric layer 70 opposite the multi-layer bottom electrode 72, as illustrated in FIG. 7B. In this example, the BO ring 88 is provided on (e.g., formed or deposited on) the surface of the first electrode layer 74-1 of the multi-layer top electrode 74 opposite the piezoelectric layer 70 around the periphery of the active region 92, as illustrated in FIG. 7C. The second electrode layer 74-2 of the multi-layer top electrode 74 is then provided on (e.g., formed or deposited on) the surface of the BO ring 88 and the exposed surface of the first electrode layer 74-1 opposite the piezoelectric layer 70, as illustrated in FIG. 7D. Lastly, as illustrated in FIG. 7E, the passivation layer 90 is provided (e.g., formed or deposited) on the surface of the BAW resonator 68 in both the active region 92 and the outer region 94.

Notably, the process of FIGS. 7A through 7E is only an example. The process may be varied to, e.g., provide the BO ring 88 at any desired position within (as opposite to on) the multi-layer top electrode 74 (or alternatively within the multi-layer bottom electrode 72) according to embodiments of the present disclosure. It should also be noted that while much of the discussion herein focuses on examples of the BAW resonator 68 of the SMR type, the BAW resonator 68 may alternatively be of the Film Bulk Acoustic Resonator (FBAR) type.

Those skilled in the art will recognize improvements and modifications to the preferred embodiments of the present disclosure. All such improvements and modifications are considered within the scope of the concepts disclosed herein and the claims that follow.

What is claimed is:

1. A Bulk Acoustic Wave (BAW) resonator, comprising:
a piezoelectric layer;
a first electrode on a first surface of the piezoelectric layer;
a second multi-layer electrode on a second surface of the piezoelectric layer opposite the first electrode on the first surface of the piezoelectric layer; and
a Border (BO) ring positioned within the second multi-layer electrode around a periphery of an active region of the BAW resonator, the BO ring being at a position within the second multi-layer electrode selected from a group consisting of: a position between two adjacent layers of the second multi-layer electrode and a position within the second multi-layer electrode that is adjacent to the piezoelectric layer.

2. The BAW resonator of claim 1 wherein the BO ring is positioned within the second multi-layer electrode at the position between the two adjacent layers of the second multi-layer electrode.

3. The BAW resonator of claim 2 wherein:
the second multi-layer electrode comprises:
a first electrode layer on the second surface of the piezoelectric layer opposite the first electrode; and
a second electrode layer on a surface of the first electrode layer opposite the piezoelectric layer; and
the two adjacent layers between which the BO ring is positioned are the first electrode layer and the second electrode layer.

4. The BAW resonator of claim 3 wherein the first electrode layer is formed of Tungsten, the second electrode layer is formed of Aluminum Copper, and the BO ring is formed of Tungsten.

5. The BAW resonator of claim 1 wherein the BO ring is positioned within the second multi-layer electrode at the position within the second multi-layer electrode that is adjacent to the piezoelectric layer.

6. The BAW resonator of claim 5 wherein:
the BO ring is on the second surface of the piezoelectric layer opposite the first electrode; and
the second multi-layer electrode comprises:
a first electrode layer on a surface of the BO ring opposite the piezoelectric layer and on the second surface of the piezoelectric layer opposite the first electrode within the BO ring; and
a second electrode layer on a surface of the first electrode layer opposite the piezoelectric layer.

7. The BAW resonator of claim 6 wherein the first electrode layer is formed of Tungsten, the second electrode layer is formed of Aluminum Copper, and the BO ring is formed of Tungsten.

8. The BAW resonator of claim 1 wherein the second multi-layer electrode is a top electrode of the BAW resonator.

9. The BAW resonator of claim 1 wherein the second multi-layer electrode is a bottom electrode of the BAW resonator.

10. The BAW resonator of claim 1 wherein the BAW resonator is a Solidly Mounted Resonator (SMR) type BAW resonator.

11. The BAW resonator of claim 1 wherein the BAW resonator is a Film Bulk

12. A method of manufacturing a Bulk Acoustic Wave (BAW) resonator, comprising:
providing an initial structure comprising a piezoelectric layer and a first electrode on a first surface of the piezoelectric layer;
providing a second multi-layer electrode on a second surface of the piezoelectric layer opposite the first electrode on the first surface of the piezoelectric layer; and
providing a Border (BO) ring positioned within the second multi-layer electrode around a periphery of an active region of the BAW resonator, the BO ring being at a position within the second multi-layer electrode selected from a group consisting of: a position between two adjacent layers of the second multi-layer electrode and a position within the second multi-layer electrode that is adjacent to the piezoelectric layer.

13. The method of claim 12 wherein providing the BO ring comprises providing the BO ring such that the BO ring is positioned within the second multi-layer electrode at the position between the two adjacent layers of the second multi-layer electrode.

14. The method of claim 13 wherein:
providing the second multi-layer electrode comprises:
providing a first electrode layer on the second surface of the piezoelectric layer opposite the first electrode; and
providing a second electrode layer on a surface of the first electrode layer opposite the piezoelectric layer; and
providing the BO ring such that the BO ring is positioned within the second multi-layer electrode at the position between the two adjacent layers of the second multi-layer electrode comprises providing the BO ring such that the BO ring is positioned between the first electrode layer and the second electrode

15. The method of claim 14 wherein the first electrode layer is formed of Tungsten, the second electrode layer is formed of Aluminum Copper, and the BO ring is formed of Tungsten.

16. The method of claim 12 wherein providing the BO ring comprises providing the BO ring such that the BO ring is positioned within the second multi-layer electrode at the position within the second multi-layer electrode that is adjacent to the piezoelectric layer.

17. The method of claim 16 wherein:
providing the BO ring comprises providing the BO ring on the second surface of the piezoelectric layer opposite the first electrode; and
providing the second multi-layer electrode comprises:
providing a first electrode layer on a surface of the BO ring opposite the piezoelectric layer and on the second surface of the piezoelectric layer opposite the first electrode within the BO ring; and
providing a second electrode layer on a surface of the first electrode layer opposite the piezoelectric layer.

18. The method of claim 17 wherein the first electrode layer is formed of Tungsten, the second electrode layer is formed of Aluminum Copper, and the BO ring is formed of Tungsten.

19. The method of claim 12 wherein the second multi-layer electrode is a top electrode of the BAW resonator.

20. The method of claim 12 wherein the second multi-layer electrode is a bottom electrode of the BAW resonator.
